(19) United States
(12) Patent Application Publication
(10) Pub. No.: US 2024/0356190 A1
(43) Pub. Date: Oct. 24, 2024

(54) TRANSMISSION LINE

(71) Applicant: Murata Manufacturing Co., Ltd., Nagaokakyo-shi (JP)

(72) Inventor: Tomohiro NAGAI, Nagaokakyo-shi (JP)

(21) Appl. No.: 18/763,068

(22) Filed: Jul. 3, 2024

Related U.S. Application Data
(63) Continuation of application No. 17/324,154, filed on May 19, 2021.
Application No. 17/324,154 is a continuation of application No. PCT/JP2019/046140, filed on Nov. 26, 2019.

(30) Foreign Application Priority Data
Dec. 6, 2018 (JP) 2018-228633

(51) Int. Cl. H01P 3/08; H01P 3/00; H01P 3/02; H05K 1/02

(52) U.S. Cl. CPC H01P 3/08; H01P 3/003; H01P 3/026; H05K 1/0237

(57) ABSTRACT

A transmission line includes a substrate, a high-frequency signal transmission line, a differential signal transmission line, and a power supply line. The substrate is insulating, extends in a predetermined direction, and internally includes each of the high-frequency signal transmission line, the differential signal transmission line, and the power supply line. The power supply line and the high-frequency signal transmission line are in parallel or substantially in parallel to each other, and the differential signal transmission line is between the power supply line and the high-frequency signal transmission line.

### CROSS REFERENCE TO RELATED APPLICATIONS

This application claims the benefit of priority to Japanese Patent Application No. 2018-228633 filed on Dec. 6, 2018 and is a Continuation application of PCT Application No. PCT/JP2019/046140 filed on Nov. 26, 2019. The entire contents of each application are hereby incorporated herein by reference.

### BACKGROUND OF THE INVENTION

### 1. Field of the Invention

The present invention relates to a transmission line including a high-frequency signal transmission line and a power supply line.

### 2. Description of the Related Art

WO 2016/163436 A discloses a multilayer resin flexible cable where a high-frequency transmission line, a differential signal line, and a power supply line are built in a single substrate.

The multilayer resin flexible cable disclosed in WO 2016/163436 A includes an insulating substrate. The insulating substrate has a first region and a second region in a width direction of the insulating substrate. The first region includes the high-frequency signal transmission line and the differential signal line. The second region includes the power supply line. The high-frequency signal transmission line and the differential signal line are arranged and aligned in a thickness direction of the insulating substrate.

However, in a configuration disclosed in WO 2016/163436 A, the power supply line and the high-frequency signal transmission line adjoin each other. Thus, a noise flowing in the power supply line is prone to propagate to the high-frequency signal transmission line.

Here, a fault caused by the noise overlapping a high-frequency signal is prone to occur.

### SUMMARY OF THE INVENTION

Preferred embodiments of the present invention provide transmission lines in each of which noise from a power supply line is less prone to propagate to a high-frequency signal transmission line.

A preferred embodiment of the present invention provides a transmission line including a substrate, a high-frequency signal transmission line, a differential signal transmission line, and a power supply line. The substrate is insulating, extends in a predetermined direction, and internally includes each of the high-frequency signal transmission line, the differential signal transmission line, and the power supply line. The power supply line and the high-frequency signal transmission line are in parallel or substantially in parallel to each other, and the differential signal transmission line is between the power supply line and the high-frequency signal transmission line.

Here, the power supply line and the high-frequency signal transmission line are spaced away from each other. Thus, a noise from the power supply line is less prone to propagate to the high-frequency signal transmission line. Further, the differential signal transmission line is between the power supply line and the high-frequency signal transmission line, such that the noise is even less prone to propagate to the high-frequency signal transmission line. In this state, the differential signal transmission line has higher noise resistance than the high-frequency signal transmission line. Accordingly, the differential signal transmission line is less prone to being affected by the noise, thus resulting in less influence on transmission of the differential signal.

Preferred embodiments of the present invention provide transmission lines in each of which a noise from a power supply line is less prone to propagate to a high-frequency signal transmission line.

The above and other elements, features, steps, characteristics, and advantages of the present invention will become more apparent from the following detailed description of the preferred embodiments with reference to the attached drawings.

### BRIEF DESCRIPTION OF THE DRAWINGS

FIG. 1 is a cross-sectional view showing a transmission line 100 according to a first preferred embodiment of the present invention.

FIG. 2 is a perspective view showing a portion of the transmission line 100 according to the first preferred embodiment of the present invention.

FIG. 3A is a plan view of an electronic device 900 including the transmission line 100 according to the first preferred embodiment of the present invention, and FIG. 3B is a cross-sectional side view showing the electronic device 900 including the transmission line 100 according to the first preferred embodiment of the present invention.

FIG. 4 is a block diagram showing circuitry of the electronic device 900 including the transmission line 100 according to the first preferred embodiment of the present invention.

FIG. 5 is a cross-sectional exploded view showing a non-limiting example of a method of manufacturing the transmission line 100 according to the first preferred embodiment of the present invention.

FIG. 6 is a cross-sectional view showing a transmission line 100A according to a second preferred embodiment of the present invention.

FIG. 7 is a cross-sectional view showing a transmission line 100B according to a third preferred embodiment of the present invention.

FIG. 8 is a cross-sectional view showing a transmission line 100C according to a fourth preferred embodiment of the present invention.

### DETAILED DESCRIPTION OF THE PREFERRED EMBODIMENTS

### First Preferred Embodiment

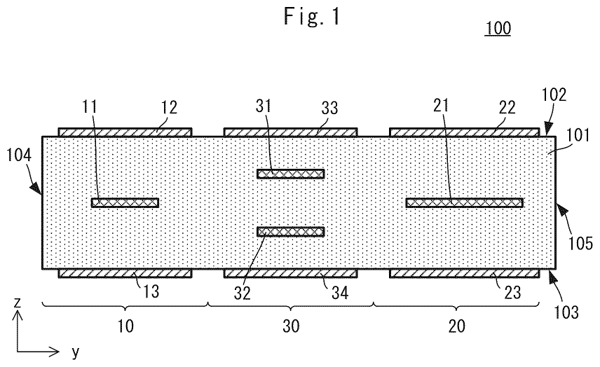

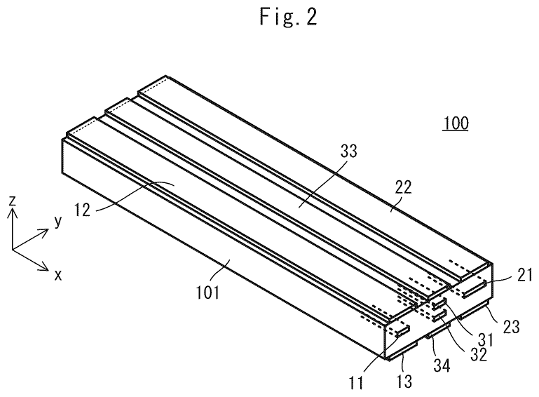

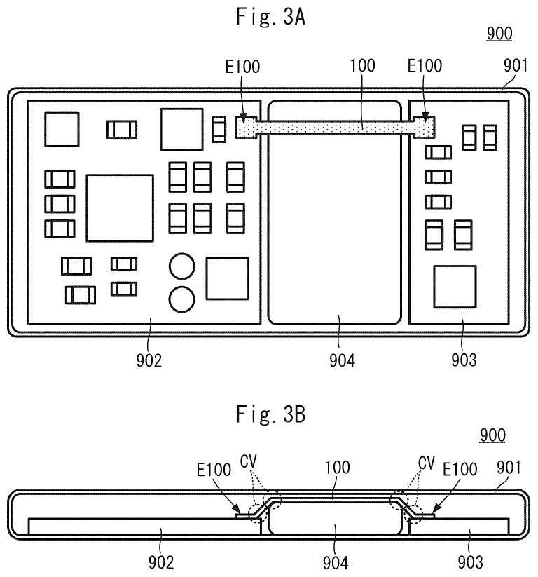

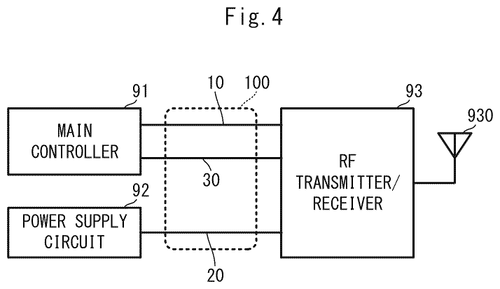

A transmission line according to a first preferred embodiment of the present invention will be described with reference to the drawings. FIG. 1 is a cross-sectional view showing a transmission line 100 according to the first preferred embodiment of the present invention. FIG. 2 is a perspective view showing a portion of the transmission line 100 according to the first preferred embodiment of the present invention. FIG. 3A is a plan view of an electronic device 900 including the transmission line 100 according to the first preferred embodiment of the present invention. FIG. 3B is a cross-sectional side view showing the electronic device 900 including the transmission line 100 according to the first preferred embodiment of the present invention. FIG. 4 is a block diagram showing circuitry of the electronic device 900 including the transmission line 100 according to the first preferred embodiment of the present invention. Note that, in each of the drawings, a thickness is exaggerated for convenience of description.

As shown in FIGS. 1 and 2, the transmission line 100 includes a substrate 101, a high-frequency signal transmission line 10, a power supply line 20, and a differential signal transmission line 30.

The substrate 101 is a flat plate extending in a predetermined direction (X-axis direction in the drawing of FIG. 2). In a thickness direction of the substrate 101 (Z-axis direction on the drawing of each of FIGS. 1 and 2), the substrate 101 includes, at one end, a first main surface 102 and includes, at another end, a second main surface 103. In perpendicular or substantially in perpendicular to a width direction of the substrate 101 (Y-axis direction in the drawing of each of FIGS. 1 and 2), the substrate 101 includes, at one end, a side surface 104 and includes, at another end, a side surface 105. Note that, the substrate 101 is not limited to a linear shape, but may include, for example, a bent section or a curved section in plan view.

The substrate 101 includes an insulating resin material that may be curved or bent in a direction perpendicular or substantially perpendicular to each of the first main surface 102 and the second main surface 103. The substrate 101 mainly includes, for example, a liquid crystal polymer.

The substrate 101 includes the high-frequency signal transmission line 10 adjacent to or in the vicinity of the side surface 104. The high-frequency signal transmission line 10 includes a signal conductor 11, a ground conductor 12, and a ground conductor 13. Each of the signal conductor 11, the ground conductor 12, and the ground conductor 13 extends in the direction where the substrate 101 extends.

The signal conductor 11 is positioned substantially at a center of the substrate 101 in the thickness direction of the substrate 101. The ground conductor 12 is located on the first main surface 102 of the substrate 101, and the ground conductor 13 is located on the second main surface 103 of the substrate 101. The signal conductor 11 opposes each of the ground conductor 12 and the ground conductor 13. The signal conductor 11 has a width smaller than a width of the ground conductor 12 and a width of the ground conductor 13.

Accordingly, the high-frequency signal transmission line 10 defines a strip line and transmits a high-frequency signal in the direction where the substrate 101 extends.

The power supply line 20 is located near the side surface 105 of the substrate 101. The power supply line 20 includes a main conductor 21, a ground conductor 22, and a ground conductor 23. Each of the main conductor 21, the ground conductor 22, and the ground conductor 23 extends in the direction where the substrate 101 extends.

The main conductor 21 is located substantially at a center of the substrate 101 in the thickness direction of the substrate 101. The ground conductor 22 is located on the first main surface 102 of the substrate 101, and the ground conductor 23 is located on the second main surface 103 of the substrate 101. The main conductor 21 opposes each of the ground conductor 22 and the ground conductor 23. The main conductor 21 has a width smaller than a width of the ground conductor 22 and a width of the ground conductor 23. However, the main conductor 21 preferably has a width that is relatively larger, in particular, a width closer to the width of the ground conductor 22 and the width of the ground conductor 23, for example.

Accordingly, the power supply line 20 transmits a power signal (DC power signal) in the direction where the substrate 101 extends.

The differential signal transmission line 30 is located substantially at a center of the substrate 101 in the width direction of the substrate 101. In other words, the differential signal transmission line 30 is located between the high-frequency signal transmission line 10 and the power supply line 20.

The differential signal transmission line 30 includes a first signal conductor 31, a second signal conductor 32, a ground conductor 33, and a ground conductor 34. Each of the first signal conductor 31, the second signal conductor 32, the ground conductor 33, and the ground conductor 34 extends in the direction where the substrate 101 extends.

The first signal conductor 31 is positioned closer to the first main surface 102 with respect to the center of the substrate 101 in the thickness direction of the substrate 101. The second signal conductor 32 is positioned closer to the second main surface 103 with respect to the center of the substrate 101 in the thickness direction of the substrate 101. In other words, the first signal conductor 31 and the second signal conductor 32 are provided in parallel or substantially in parallel to each other in the direction where the substrate 101 extends, at a predetermined distance from each other in the thickness direction of the substrate 101.

The ground conductor 33 is located on the first main surface 102 of the substrate 101, and the ground conductor 34 is located on the second main surface 103 of the substrate 101. The first signal conductor 31 opposes the ground conductor 33, and the second signal conductor 32 opposes the ground conductor 34. The first signal conductor 31 has a width equal or substantially equal to a width of the second signal conductor 32, and the width of each of the first signal conductor 31 and the second signal conductor 32 is smaller than a width of the ground conductor 33 and a width of the ground conductor 34.

Accordingly, the differential signal transmission line 30 includes each of the first signal conductor 31 and the second signal conductor 32 as a differential transmission line to transmit a differential signal in the direction where the substrate 101 extends.

As has been described above, the transmission line 100 includes the high-frequency signal transmission line 10, the power supply line 20, and the differential signal transmission line 30 between the high-frequency signal transmission line 10 and the power supply line 20.

Here, the high-frequency signal transmission line 10 and the power supply line 20 are spaced away from each other at a distance equal or substantially equal to a size of the differential signal transmission line 30. Accordingly, a noise from the power supply line 20, for example, a switching noise overlapping the power signal transmitted from the power supply line 20, is less prone to propagate to the high-frequency signal transmission line 10.

Note that, on the first main surface 102, the ground conductor 12, the ground conductor 22, and the ground conductor 33 are located at a predetermined distance from each other in the Y-axis direction. Similarly, on the second main surface 103, the ground conductor 13, the ground conductor 23, and the ground conductor 34 are located at a predetermined distance from each other in the Y-axis direction. Accordingly, coupling via the ground conductors above is less prone to occur.

Further, between the high-frequency signal transmission line 10 and the power supply line 20, the differential signal transmission line 30 includes the first signal conductor 31 and the second signal conductor 32. Accordingly, the noise from the power supply line 20 is significantly reduced or prevented within the differential signal transmission line 30, and the noise is even less prone to propagate to the high-frequency signal transmission line 10.

In this state, as has been described above, each of the first signal conductor 31 and the second signal conductor 32 defines and functions as the differential transmission line. Accordingly, the differential signal transmission line 30 is highly resistant to the noise from the power supply line 20. In other words, even when the noise from the power supply line 20 propagates to the differential signal transmission line 30, an influence on transmission of the differential signal is limited.

Accordingly, in the transmission line 100, even when the high-frequency signal, the differential signal, and power signal are transmitted from the substrate 101 as a single substrate, a fault due to mutual interference between these signals is less prone to occur, and transmission characteristics for each of the signals is less prone to be degraded.

Further, the transmission line 100, which transmits each of the high-frequency signal, the differential signal, and the power signal, may be thinly structured.

As shown in FIGS. 3A and 3B, the electronic device 900 includes the transmission line 100, a housing 901, a circuit board 902, a circuit board 903, and a battery 904. The electronic device 900 may be, for example, a portable information communication terminal.

The transmission line 100, the circuit board 902, the circuit board 903, and the battery 904 are accommodated in the housing 901. The circuit board 902 and the circuit board 903 are spaced away from each other. The battery 904 is between the circuit board 902 and the circuit board 903.

In addition, the transmission line 100 includes an external connection terminal (omitted in FIGS. 1 and 2) at each end E100 of the transmission line 100 in a direction where the transmission line 100 extends. In this state, the external connection terminal is provided to each of the high-frequency signal transmission line 10, the power supply line 20, and the differential signal transmission line 30. As shown in FIGS. 3A and 3B, the transmission line 100 connects the circuit board 902 and the circuit board 903 via the external connection terminal at each end E100.

As shown in FIG. 4, the circuit board 902 includes, for example, a main controller 91 and a power supply circuit 92 thereon. As shown in FIG. 4, the circuit board 903 includes, for example, an RF transmitter/receiver 93 thereon. The RF transmitter/receiver 93 is connected to an antenna 930 (not shown in FIGS. 3A and 3B).

Accordingly, each of the high-frequency signal, the differential signal, and the power signal is transmitted between the RF transmitter/receiver 93 and the main controller 91 or the power supply circuit 92 . . . . Here, as shown in FIG. 4, the main controller 91 and the RF transmitter/receiver 93 are connected as a circuit via the high-frequency signal transmission line 10 and the differential signal transmission line 30. Further, the power supply circuit 92 and the RF transmitter/receiver 93 are connected via the power supply line 20.

In terms of structure, the circuit board 902 including the main controller 91 and the power supply circuit 92 may be connected to the circuit board 903 including the RF transmitter/receiver 93, via the high-frequency signal transmission line 10, the differential signal transmission line 30, and the power supply line 20. In other words, as has been described, the circuit board 902 and the circuit board 903 may be connected via the transmission line 100.

With the transmission line 100 according to the present preferred embodiment, the high-frequency signal transmission line 10, the differential signal transmission line 30, and the power supply line 20 are collectively wired by the transmission line 100 as a single transmission line. Accordingly, wiring is able to be performed easily in the electronic device 900.

Further, the transmission line 100 may be thinly structured, for example, to be curved in the direction perpendicular or substantially perpendicular to each of the first main surface 102 and the second main surface 103. Thus, as shown in FIG. 3B, the transmission line 100 may have a curved section CV and may be thus provided along an outer shape of the battery 904. Accordingly, the wiring is able to be performed more freely in the electronic device 900.

In the transmission line 100, the ground conductor 12 and the ground conductor 13 are not connected. However, the ground conductor 12 and the ground conductor 13 may be connected via a ground conductor (interlayer connection conductor) extending in a thickness direction of the transmission line 100 (see a structure of a second preferred embodiment of the present invention described below). Similarly, the ground conductor 22 and the ground conductor 23 may be connected via a ground conductor (interlayer connection conductor) extending in the thickness direction of the transmission line 100, and the ground conductor 33 and the ground conductor 34 may be connected via a ground conductor (interlayer connection conductor) extending in the thickness direction of the transmission line 100.

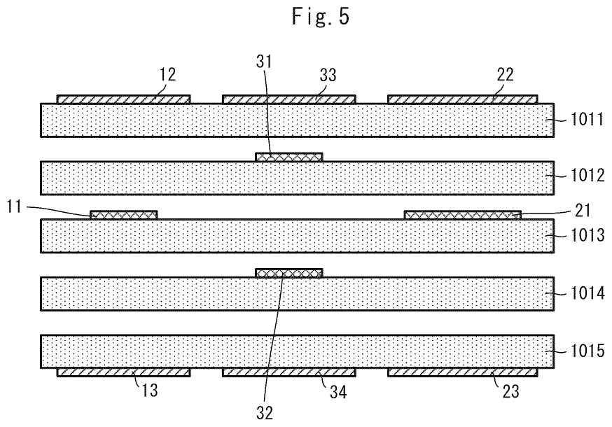

The transmission line 100 described above may be manufactured by, for example, a non-limiting example of a method as follows. FIG. 5 is a cross-sectional exploded view showing the non-limiting example of the method of manufacturing the transmission line according to the first preferred embodiment of the present invention.

A plurality of insulating resin materials, which are an insulating resin material 1011, an insulating resin material 1012, an insulating resin material 1013, an insulating resin material 1014, and an insulating resin material 1015, each having a predetermined thickness, are prepared.

As shown in FIG. 5, the ground conductor 12, the ground conductor 22, and the ground conductor 33 are located on one main surface of the insulating resin material 1011. The first signal conductor 31 is located on one main surface of the insulating resin material 1012. The signal conductor 11 and the main conductor 21 are located on one main surface of the insulating resin material 1013. The second signal conductor 32 is located on one main surface of the insulating resin material 1014. The ground conductor 13, the ground conductor 23, and the ground conductor 34 are located on the other main surface of the insulating resin material 1015.

The plurality of insulating resin materials 1011 to 1015, each including the corresponding conductor(s) thereon, are laminated. Then, a laminate, which the insulating resin materials 1011 to 1015 have been laminated, is heat pressed.

By the method described above, the transmission line 100 is easily provided.

### Second Preferred Embodiment

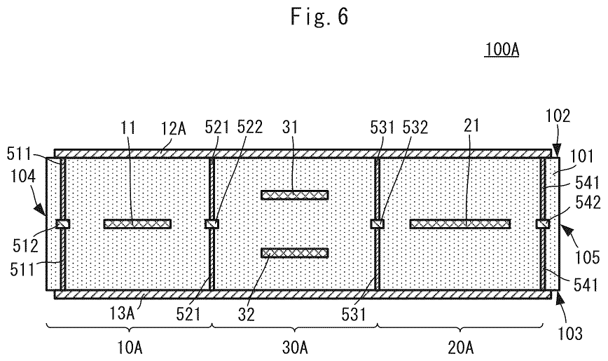

FIG. 6 is a cross-sectional view showing a transmission line 100A according to a second preferred embodiment of the present invention. As shown in FIG. 6, unlike the transmission line 100 of the first preferred embodiment, the transmission line 100A according to the second preferred embodiment includes a shared ground conductor on each of a first main surface 102 and a second main surface 103, and additionally includes a ground conductor extending in a thickness direction of the transmission line 100A. Other features and structures of the transmission line 100A are the same as or similar to those of the transmission line 100, and thus a detailed description thereof will be omitted as appropriate.

The transmission line 100A includes a ground conductor 12A, a ground conductor 13A, an interlayer connection conductor 511, an interlayer connection conductor 521, an interlayer connection conductor 531 and an interlayer connection conductor 541, an auxiliary conductor 512, an auxiliary conductor 522, an auxiliary conductor 532, and an auxiliary conductor 542.

The ground conductor 12A is located on the first main surface 102 of a substrate 101. The ground conductor 13A is located on the second main surface 103 of the substrate 101.

A high-frequency signal transmission line 10A includes a signal conductor 11, the ground conductor 12A, and the ground conductor 13A. A power supply line 20A includes a main conductor 21, the ground conductor 12A, and the ground conductor 13A. A differential signal transmission line 30A includes a first signal conductor 31, a second signal conductor 32, the ground conductor 12A, and the ground conductor 13A.

The interlayer connection conductor 511 connects the ground conductor 12A and the ground conductor 13A via the auxiliary conductor 512 that is located at a middle position of the interlayer connection conductor 511 in a thickness direction of the substrate 101. Accordingly, each of the interlayer connection conductor 511 and the auxiliary conductor 512 defines and functions as a ground conductor extending in the thickness direction.

The interlayer connection conductor 511 and the auxiliary conductor 512 are provided between a side surface 104 of the substrate 101 and the signal conductor 11 in a width direction of the substrate 101. In other words, the interlayer connection conductor 511 and the auxiliary conductor 512 are provided at an end of the high-frequency signal transmission line 10A near the side surface 104.

The interlayer connection conductor 521 connects the ground conductor 12A and the ground conductor 13A via the auxiliary conductor 522 that is located at a middle position of the interlayer connection conductor 521 in the thickness direction of the substrate 101. Accordingly, each of the interlayer connection conductor 521 and the auxiliary conductor 522 defines and functions as a ground conductor extending in the thickness direction.

The interlayer connection conductor 521 and the auxiliary conductor 522 are provided between the signal conductor 11 and the first signal conductor 31 or the second signal conductor 32 in the width direction of the substrate 101. In other words, the interlayer connection conductor 521 and the auxiliary conductor 522 are provided at a boundary between the high-frequency signal transmission line 10A and the differential signal transmission line 30A in the width direction of the substrate 101.

The interlayer connection conductor 531 connects the ground conductor 12A and the ground conductor 13A via the auxiliary conductor 532 that is located at a middle position of the interlayer connection conductor 531 in the thickness direction of the substrate 101. Accordingly, each of the interlayer connection conductor 531 and the auxiliary conductor 532 defines and functions as a ground conductor extending in the thickness direction.

The interlayer connection conductor 531 and the auxiliary conductor 532 are provided between the main conductor 21 and the first signal conductor 31 or the second signal conductor 32 in the width direction of the substrate 101. In other words, the interlayer connection conductor 531 and the auxiliary conductor 532 are provided at a boundary between the differential signal transmission line 30A and the power supply line 20A in the width direction of the substrate 101.

The interlayer connection conductor 541 connects the ground conductor 12A and the ground conductor 13A via the auxiliary conductor 542 that is located at a middle position of the interlayer connection conductor 541 in the thickness direction of the substrate 101. Accordingly, each of the interlayer connection conductor 541 and the auxiliary conductor 542 defines and functions as a ground conductor extending in the thickness direction.

The interlayer connection n conductor 541 and the auxiliary conductor 542 are provided between a side surface 105 of the substrate 101 and the main conductor 21 in the width direction of the substrate 101. In other words, the interlayer connection conductor 541 and the auxiliary conductor 542 are provided at an end of the power supply line 20A near the side surface 105.

As has been described, with the transmission line 100A, the ground conductor extending in the thickness direction is provided at the boundary between the high-frequency signal transmission line 10A and the differential signal transmission line 30A, and at the boundary between the differential signal transmission line 30A and the power supply line 20A. Accordingly, a noise from the main conductor 21 of the power supply line 20A is shielded by the ground conductors extending in the thickness direction. Accordingly, the noise is less prone to propagate to the high-frequency signal transmission line 10A.

Further, in the second preferred embodiment, unlike the first preferred embodiment, the ground conductor 12A is shared on the first main surface 102, and the ground conductor 13A is shared on the second main surface 103. With these shared ground conductors, each having a planar shape and an increased ground area, undesirable radiation is less prone to be leaked to outside from each of the high-frequency signal transmission line 10A, power supply line 20A, and the differential signal transmission line 30A in the transmission line 100A.

Note that, even when the ground conductor extending in the thickness direction is provided at any one of the boundaries, i.e., the boundary between the high-frequency signal transmission line 10A and the differential signal transmission line 30A or the boundary between the differential signal transmission line 30A and the power supply line 20A, the noise is able to be shielded. However, when the ground conductor extending in the thickness direction is provided at each of the boundaries, the noise is able to be further shielded.

The ground conductor extending in the thickness direction may be provided on each of the side surface 104 (an outer wall surface of the laminate) near the high-frequency signal transmission line 10A and the side surface 105 (an outer wall surface of the laminate) near the power supply line 20A. Accordingly, the undesirable radiation, generated at each of the high-frequency signal transmission line 10A, power supply line 20A, and the differential signal transmission line 30A in the transmission line 100A, is less prone to be leaked to outside through the side surfaces of the substrate 101 in the transmission line 100A.

Note that, the ground conductor extending in the thickness direction may not be provided on the side surface 104 near the high-frequency signal transmission line 10A or the side surface 105 near the power supply line 20A. Accordingly, an overall width of the transmission line 100A is reduced, thus resulting in the transmission line 100A in smaller size.

### Third Preferred Embodiment

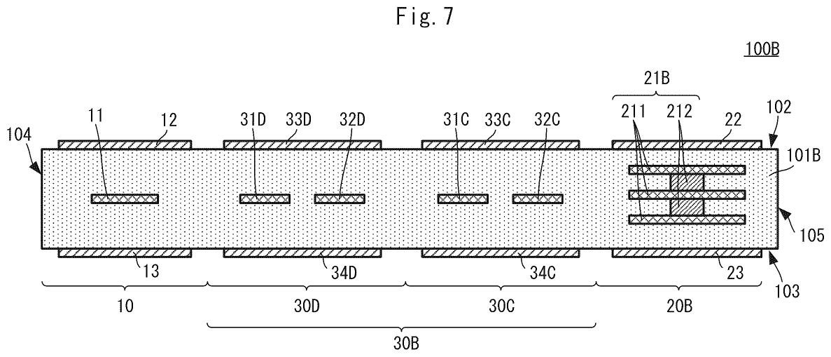

FIG. 7 is a cross-sectional view showing a transmission line 100B according to a third preferred embodiment of the present invention. As shown in FIG. 7, the transmission line 100B according to the third preferred embodiment includes a differential signal transmission line 30B and a power supply line 20B that respectively have different structures from those of the differential signal transmission line 30 and the power supply line 20 in the transmission line 100 of the first preferred embodiment. Other features and structures of the transmission line 100B are the same as or similar to those of the transmission line 100, and thus a detailed description thereof will be omitted as appropriate.

As shown in FIG. 7, the transmission line 100B includes the power supply line 20B and the differential signal transmission line 30B.

The power supply line 20B includes a main conductor 21B, a ground conductor 22, and a ground conductor 23. The main conductor 21B includes a plurality of plate conductors 211 and a plurality of connection conductors 212. The plurality of plate conductors 211 are aligned in a thickness direction of a substrate 101. The plurality of connection conductors 212 connect the plurality of plate conductors 211 in the thickness direction. Accordingly, in the power supply line 20B, the main conductor 21B has a cross-sectional area (cross-sectional area through which a power supply current flows) increased. Accordingly, in the power supply line 20B, a power transmission loss is reduced.

The differential signal transmission line 30B includes a control signal transmission line 30C and a data transmission line 30D. The control signal transmission line 30C includes a first signal conductor 31C, a second signal conductor 32C, a ground conductor 33C, and a ground conductor 34C. The first signal conductor 31C and the second signal conductor 32C are located substantially at a center of the substrate 101 in the thickness direction of the substrate 101, and are spaced away from each other in a width direction of the substrate 101. The data transmission line 30D includes a first signal conductor 31D, a second signal conductor 32D, a ground conductor 33D, and a ground conductor 34D. The first signal conductor 31D and the second signal conductor 32D are located substantially at a center of the substrate 101 in the thickness direction of the substrate 101, and are spaced away from each other in the width direction of the substrate 101.

The data transmission line 30D is located closer to a high-frequency signal transmission line 10 with respect to the control signal transmission line 30C. In other words, the control signal transmission line 30C is located closer to the power supply line 20B with respect to the data transmission line 30D.

The data transmission line 30D transmits data, for example, binarized data. The data transmission line 30D transmits the data at a clock frequency that is lower than a frequency of a high-frequency signal transmitted by the high-frequency signal transmission line 10.

The control signal transmission line 30C transmits a control signal for, for example, a switching element of an RF transmitter/receiver 93. The control signal is transmitted at lower frequency than the clock frequency for the data.

Accordingly, in the transmission line 100B, the high-frequency signal transmission line 10 is further spaced away from the power supply line 20B. Thus, a noise from the power supply line 20B is even less prone to propagate to the high-frequency signal transmission line 10.

Further, the control signal transmission line 30C is located closer to the power supply line 20B with respect to the data transmission line 30D. The control signal transmission line 30C transmits the control signal at lower frequency that is relatively resistant to noise, and the data transmission line 30D transmits the data at higher frequency, i.e., the clock frequency, that is relatively less resistant to noise. Thus, as exemplified by the differential signal transmission line 30B, even when the transmission line 100B includes the data transmission line 30D, the noise from the power supply line 20B is less prone to propagate to the data transmission line 30D.

Accordingly, even when the transmission line 100B further includes transmission lines to transmit various signals or data in the substrate 101 as a single substrate, transmission characteristics for each of the signals or data is less prone to be degraded. Further, the transmission line 100B may be easily curved. Here, even when including the transmission lines to transmit various signals or data, the transmission line 100B is structured more freely.

### Fourth Preferred Embodiment

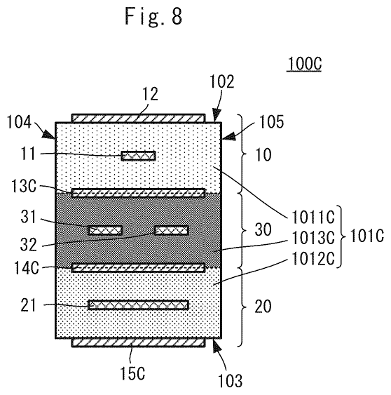

FIG. 8 is a cross-sectional view showing a transmission line 100C according to a fourth preferred embodiment of the present invention. As shown in FIG. 8, the transmission line 100C according to the fourth preferred embodiment includes a high-frequency signal transmission line 10, a differential signal transmission line 30, and a power supply line 20, each provided in a different direction from in the transmission line 100 according to the first preferred embodiment. Other features and structures of the transmission line 100C are similar to those of the transmission line 100, and thus a detailed description thereof will be omitted as appropriate.

In the transmission line 100C, the high-frequency signal transmission line 10, the differential signal transmission line 30, and the power supply line 20 are sequentially aligned in a thickness direction of a substrate 101C. More specifically, the substrate 101C has a first main surface 102 and a second main surface 103, and the high-frequency signal transmission line 10, the differential signal transmission line 30, and the power supply line 20 are sequentially provided from the first main surface 102 toward the second main surface 103.

The high-frequency signal transmission line 10 includes a signal conductor 11, a ground conductor 12 on the first main surface 102, and a ground conductor 13C. The signal conductor 11 is provided between the ground conductor 12 and the ground conductor 13C.

The differential signal transmission line 30 includes a first signal conductor 31, a second signal conductor 32, the ground conductor 13C, and a ground conductor 14C. The ground conductor 13C is shared with the high-frequency signal transmission line 10. The first signal conductor 31 and the second signal conductor 32 are aligned in a width direction of the substrate 101C. The first signal conductor 31 and the second signal conductor 32 are provided between the ground conductor 13C and the ground conductor 14C.

The power supply line 20 includes a main conductor 21, the ground conductor 14C, and a ground conductor 15C on the second main surface 103. The ground conductor 14C is shared with the differential signal transmission line 30. The main conductor 21 is provided between the ground conductor 14C and the ground conductor 15C.

Accordingly, similarly to each of the foregoing preferred embodiments, a noise from the power supply line 20 is less prone to propagate to the high-frequency signal transmission line 10. Further, the transmission line 100C may be reduced in width.

Note that, the thickness is emphasized in FIG. 8, but in the transmission line 100C, the thickness may actually be smaller than the width. Accordingly, similarly to the transmission line in each of the foregoing preferred embodiments, the transmission line 100C may be curved.

In the transmission line 100C, the substrate 101C further includes a first section 1011C, a second section 1012C, and a third section 1013C. The high-frequency signal transmission line 10 is located in the first section 1011C. The power supply line 20 is located in the second section 1012C. The differential signal transmission line 30 is located in the third section 1013C.

The first section 1011C, the second section 1012C, and the third section 1013C are preferably made of different materials from each other. Here, “made of different materials from each other” includes a case where these sections are made of the same or similar main material, but a content ratio of each of other materials to the main material varies among these materials.

For example, the first section 1011C is made of, for example, an insulating resin material, and the third section 1013C is made of, for example, the insulating resin material to which a magnetic substance is added as a filler. Accordingly, a degree of coupling of the differential signal transmission line 30 is able to be significantly improved without affecting transmission characteristics of the high-frequency signal transmission line 10.

Further, the second section 1012C is made of, for example, a material greater in heat resistance and heat dissipation than the material of the first section 1011C. Then, while the transmission characteristics of the high-frequency signal transmission line 10 is not affected, the power supply line 20 is significantly improved in heat resistance and heat dissipation, thus resulting in the transmission line 100C having higher reliability.

As has been described, by selecting a material for each section of the substrate 101, the characteristics and reliability of each of the high-frequency signal transmission line 10, the differential signal transmission line 30, and the power supply line 20 are able to be significantly improved.

Further, the plurality of insulating resin materials are laminated to provide the substrate 101C, and the first section 1011C, the second section 1012C, and the third section 1013C are easily structured.

Note that, in the description of the transmission line 100C, the first section 1011C, the second section 1012C, and the third section 1013C are made of different materials from each other. However, in accordance with predetermined characteristics of the transmission line 100C, one of the sections described above may be made of a material different from those of the other two, while the other two share the same or similar material.

Note that, the features and structures described in each of the foregoing preferred embodiments may be combined while providing the advantageous effects in each combination.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A transmission line comprising:
a substrate that is insulating and extends in a predetermined direction;
a high-frequency signal transmission line included in the substrate;
a differential signal transmission line included in the substrate; and
a power supply line included in the substrate; wherein:
the power supply line and the high-frequency signal transmission line are in parallel or substantially in parallel to each other;
the differential signal transmission line is between the power supply line and the high-frequency signal transmission line; and
in the substrate where the high-frequency signal transmission line and the differential signal transmission line are closest and parallel or substantially parallel to each other, the power supply line, the differential signal transmission line, and the high-frequency signal transmission line are aligned with each other in a thickness direction of the substrate.

2. The transmission line according to claim 1, further comprising a ground conductor between at least one of the power supply line and the differential signal transmission line or the differential signal transmission line and the high-frequency signal transmission line.

3. The transmission line according to claim 1, wherein
the differential signal transmission line includes a data transmission line and a control signal transmission line; and
the data transmission line is closer to the high-frequency signal transmission line with respect to the control signal transmission line.

4. The transmission line according to claim 1, wherein the substrate includes a curved section at a middle position of the substrate in the direction in which the substrate extends.

5. The transmission line according to claim 1, wherein
the substrate includes:
a first section where the high-frequency signal transmission line is located;
a second section where the power supply line is located; and
a third section where the differential signal transmission line is located; and
the first section, the second section, and the third section are made of different materials from each other.

6. The transmission line according to claim 1, wherein the substrate includes a plurality of insulating resin materials that separate the high-frequency signal transmission line, the differential signal transmission line included in the substrate, and the power supply line from one another.

7. The transmission line according to claim 1, further comprising a first ground conductor on a first main surface of the substrate.

8. The transmission line according to claim 7, wherein a width of the differential signal transmission line is smaller than a width of the first ground conductor.

9. The transmission line according to claim 7, further comprising a second ground conductor on a second main surface of the substrate that opposes the first main surface of the substrate.

10. The transmission line according to claim 9, wherein the first ground conductor and the second ground conductor are not connected to each other.

11. The transmission line according to claim 1, wherein
the differential signal transmission line includes a first differential signal transmission line and a second differential signal transmission line; and
a width of the first differential signal transmission line is equal or substantially equal to a width of the second differential signal transmission line.

12. The transmission line according to claim 1, wherein
the differential signal transmission line includes a data transmission line and a control signal transmission line; and
the control signal transmission line is located closer to the power supply line with respect to the data transmission line.

13. The transmission line according to claim 5, wherein
the first section includes an insulating resin material;
the second section includes a material that is higher in heat resistance and heat dissipation than the insulating resin material of the first section; and
the third section includes an insulating resin material with a filler magnetic substance.

14. The transmission line according to claim 1, wherein the high-frequency signal transmission line and the power supply line are spaced away from each other at a distance equal or substantially equal to a size of the differential signal transmission line.
